(19) United States
(12) Patent Application Publication
(10) Pub. No.: US 2025/0227885 A1
(43) Pub. Date: Jul. 10, 2025

(54) THERMAL DIFFUSION DEVICE AND ELECTRONIC DEVICE

(71) Applicant: Murata Manufacturing Co., Ltd., Nagaokakyo-shi (JP)

(72) Inventors: Tatsuhiro NUMOTO, Nagaokakyo-shi (JP); Hiroshi FUKUDA, Nagaokakyo-shi (JP)

(21) Appl. No.: 19/095,544

(22) Filed: Mar. 31, 2025

Related U.S. Application Data
(63) Continuation of application No. PCT/JP2023/035415, filed on Sep. 28, 2023.

(30) Foreign Application Priority Data
Oct. 6, 2022 (JP) 2022-161754

(51) Int. Cl. H05K 7/20

(52) U.S. Cl. CPC H05K 7/20336

(57) ABSTRACT

A vapor chamber that includes: a housing having a first internal surface and a second internal surface opposing each other in a thickness direction so as to define an internal space; a working medium in the internal space of the housing; a wick in the internal space of the housing; and a first support body in the internal space of the housing between the wick and either one of the first internal surface and the second internal surface of the housing, wherein the wick has one or more through-holes, and wherein the wick, in an area overlapping the first support body, includes: at least one of the one or more through-holes, and a first protrusion that is closer to the first support body in the thickness direction than a peripheral edge of the at least one of the one or more through-holes in the area.

### CROSS REFERENCE TO RELATED APPLICATIONS

The present application is a continuation of International application No. PCT/JP2023/035415, filed Sep. 28, 2023, which claims priority to Japanese Patent Application No. 2022-161754, filed Oct. 6, 2022, the entire contents of each of which are incorporated herein by reference.

### TECHNICAL FIELD

The present disclosure relates to a thermal diffusion device and an electronic device.

### BACKGROUND ART

Highly integrated elements with enhanced performance have been increasing heat generation in these years. In addition, as products become smaller, the heat generation density of the products increases, so effective heat dissipation countermeasures are crucial. This situation is particularly notable in the field of mobile terminals such as smartphones and tablets. As countermeasures against heat, components such as a graphite sheet are usually used, but they do not transport a sufficient amount of heat. Thus, use of various other countermeasures against heat has been studied. Among these, the study of use of a vapor chamber, which is a planar heat pipe, as a thermal diffusion device capable of highly effectively diffusing heat has progressed.

A vapor chamber has a structure including a housing in which a working medium (also referred to as an operating fluid) and a wick that transports the working medium with a capillary action are enclosed. The working medium absorbs heat from a heating element such as an electronic component at a vaporizing portion that absorbs heat from the heating element, evaporates in the vapor chamber, then moves in the vapor chamber to be cooled, and returns to the liquid phase. The working medium returned to the liquid phase moves to the vaporizing portion in the heating element again with the capillary action of the wick, and cools the heating element. With the repetition of this operation, the vapor chamber can independently operate without using an external power, and quickly diffuse heat two-dimensionally using evaporative latent heat and condensed latent heat of the working medium.

Patent Document 1 discloses a vapor chamber that includes a housing, an operating fluid, a microchannel, and a sheet-shaped wick. The housing includes an upper housing sheet and a lower housing sheet facing each other and having outer edge portions joined with each other, and has an internal space. The operating fluid is enclosed in the internal space. The microchannel is disposed in the lower housing sheet in the internal space, and forms a flow path of the operating fluid. The wick is disposed in the internal space of the housing, and in contact with the microchannel. The area over which the wick and the microchannel are in contact with each other is 5% to 40% of the area of the internal space when viewed in plan.

Patent Document 1: International Publication No. 2021/229961

### SUMMARY OF DISCLOSURE

FIG. 1 in Patent Document 1 illustrates, as a vapor chamber according to an embodiment, a structure in which the wick is held between protruding portions of the microchannel disposed at the lower housing sheet and props disposed at the upper housing sheet. Patent Document 1 describes that the wick has multiple fine pores, and the pores are formed by, for example, etching.

In such a vapor chamber, the wick and the props may be joined for improving the strength, but the pores of the wick may be closed by the props. Also in a case where the wick and the protruding portions of the microchannel are to be joined, the pores of the wick may be similarly closed by the protruding portions. Closing the pores of the wick prevents smooth gas-liquid exchange of the operating fluid, and thus causes reduction of a maximum amount of heat transport Qmax.

Not only the vapor chamber, but also a thermal diffusion device capable of diffusing heat with the same mechanism as the vapor chamber also has the above issue.

The present disclosure is made to address the above issue, and aims to provide a thermal diffusion device capable of improving the maximum amount of heat transport. The present disclosure further aims to provide an electronic device including the thermal diffusion device.

A thermal diffusion device according to the present disclosure includes: a housing having a first internal surface and a second internal surface opposing each other in a thickness direction so as to define an internal space; a working medium in the internal space of the housing; a wick in the internal space of the housing; and a first support body in the internal space of the housing between the wick and either one of the first internal surface and the second internal surface of the housing, wherein the wick has one or more through-holes extending therethrough in the thickness direction, and wherein the wick, in an area overlapping the first support body in a plan view of the first internal surface, includes: at least one of the one or more through-holes, and a first protrusion that is closer to the first support body in the thickness direction than a peripheral edge of the at least one of the one or more through-holes in the area.

The electronic device according to the present disclosure includes a thermal diffusion device according to the present disclosure.

According to the present disclosure, a thermal diffusion device capable of improving the maximum amount of heat transport can be provided. According to the present disclosure, an electronic device including the thermal diffusion device can further be provided.

### BRIEF DESCRIPTION OF THE DRAWINGS

FIG. 1 is a schematic perspective view of an example of a thermal diffusion device according to a first embodiment of the present disclosure.

FIG. 2 is a schematic cross-sectional view of an example of the thermal diffusion device according to the first embodiment of the present disclosure.

FIG. 3 is a schematic cross-sectional view of examples of a housing and a wick of the thermal diffusion device according to the first embodiment of the present disclosure.

FIG. 4 is a schematic plan view of an example of the wick illustrated in FIG. 3.

FIG. 5 is a schematic cross-sectional view of examples of a housing and a wick of a thermal diffusion device according to a second embodiment of the present disclosure.

FIG. 6 is a schematic plan view of an example of the wick illustrated in FIG. 5.

FIG. 7 is a schematic cross-sectional view of examples of a housing and a wick of a thermal diffusion device according to a third embodiment of the present disclosure.

FIG. 8 is a schematic cross-sectional view of examples of the housing and the wick at different positions from those illustrated in FIG. 7.

FIG. 9 is a schematic plan view of an example of the wick illustrated in FIG. 7 and FIG. 8.

FIG. 10 is a schematic cross-sectional view of other examples of a housing and a wick of a thermal diffusion device according to the third embodiment of the present disclosure.

FIG. 11 is a schematic cross-sectional view of examples of a housing and a wick of a thermal diffusion device according to a fourth embodiment of the present disclosure.

FIG. 12 is a schematic plan view of an example of the wick illustrated in FIG. 11.

FIG. 13 is a schematic cross-sectional view of a first modification example of the shape of a first protrusion.

FIG. 14 is a schematic cross-sectional view of a second modification example of the shape of a first protrusion.

FIG. 15 is a schematic cross-sectional view of a third modification example of the shape of a first protrusion.

FIG. 16 is a schematic perspective view of a thermal diffusion device according to a first modification example of the present disclosure.

FIG. 17 is a schematic cross-sectional view of the thermal diffusion device according to the first modification example of the present disclosure.

FIG. 18 is a schematic perspective view of a thermal diffusion device according to a second modification example of the present disclosure.

FIG. 19 is a schematic cross-sectional view of the thermal diffusion device according to the second modification example of the present disclosure.

### DESCRIPTION OF THE PREFERRED EMBODIMENTS

Hereafter, a thermal diffusion device according to the present disclosure is described.

The present disclosure is not limited to embodiments described below, and is also applicable by being changed as appropriate within the scope not departing from the gist of the present disclosure. A combination of two or more preferable components of the present disclosure described below is also included in the present disclosure.

In a thermal diffusion device according to the present disclosure, a wick located in an area overlapping a first support body in a plan view of a first internal surface of a housing has at least one through-hole, and a first protrusion that is located closer to the first support body in the thickness direction than a peripheral edge of the through-hole located in the area. Thus, the area of the wick in which the through-hole is closed is reduced further than the area of the wick that does not include the first protrusion and that is disposed in an internal space of the housing. Thus, the maximum amount of heat transport Qmax can be improved.

In the thermal diffusion device according to the present disclosure, the first protrusion may be in no contact with the first support body, but preferably is in contact with the first support body.

In the thermal diffusion device according to the present disclosure, the first protrusion may be disposed at the peripheral edge of the through-hole. In that case, the through-hole has a first through-hole having a peripheral edge at which the first protrusion is disposed. The first protrusion may be disposed at a position different from the peripheral edge of the through-hole. More specifically, a portion where the first protrusion is disposed may have a hole extending through the wick or does not have to have a hole extending through the wick.

In the thermal diffusion device according to the present disclosure, the first support body is disposed between the wick and either one of a first internal surface and a second internal surface of the housing. The first support body is, for example, a prop that supports the housing and the wick. Alternatively, the first support body may be a protrusion that holds a working medium in a liquid phase (more specifically, a protruding portion of the microchannel described in Patent Document 1).

The thermal diffusion device according to the present disclosure may include a second support body in the internal space of the housing. The second support body is disposed on either one of the first internal surface and the second internal surface of the housing opposite to the internal surface located closer to the first support body. For example, when the first support body is disposed between the wick and the second internal surface of the housing, the second support body may be disposed between the wick and the first internal surface of the housing.

When the first support body is a prop, the second support body is preferably a protrusion. On the other hand, when the second support body is a protrusion, the first support body is preferably a prop.

In the thermal diffusion device according to the present disclosure, the wick located in an area overlapping the first support body in a plan view of the first internal surface of the housing may include a second protrusion that protrudes away from the first support body in a direction opposite to the direction in which the first protrusion protrudes.

It goes without saying that embodiments described below are mere examples, and components in different embodiments may be partially replaced with each other or combined with each other. In embodiments from a second embodiment, components the same as those in the first embodiment are not described, and only different points are described. Particularly, the same or similar operations and effects of the same or similar components are not described for each embodiment.

In the following description, when the embodiments are not particularly distinguished from one another, the thermal diffusion device is simply referred to as “a thermal diffusion device according to the present disclosure”.

A vapor chamber is described below as an example of a thermal diffusion device according to an embodiment of the present disclosure. The thermal diffusion device according to the present disclosure is also applicable to a thermal diffusion device such as a heat pipe.

The drawings described below are schematic, and, for example, the dimensions or the scale of aspect ratio may be different from those of an actual product.

Herein, terms indicating the relationship between components (such as “vertical”, “parallel”, or “orthogonal”) and terms indicating the shape of each component not only refer to their literal meanings in a strict sense, but also encompass substantially equivalent variations, such as differences of, for example, approximately a few percent.

### First Embodiment

In a thermal diffusion device according to a first embodiment of the present disclosure, a first support body is a prop. The wick located in an area overlapping the first support body in a plan view of a first internal surface has at least one through-hole, and a first protrusion located closer to the first support body in the thickness direction than a peripheral edge of the through-hole located in the area.

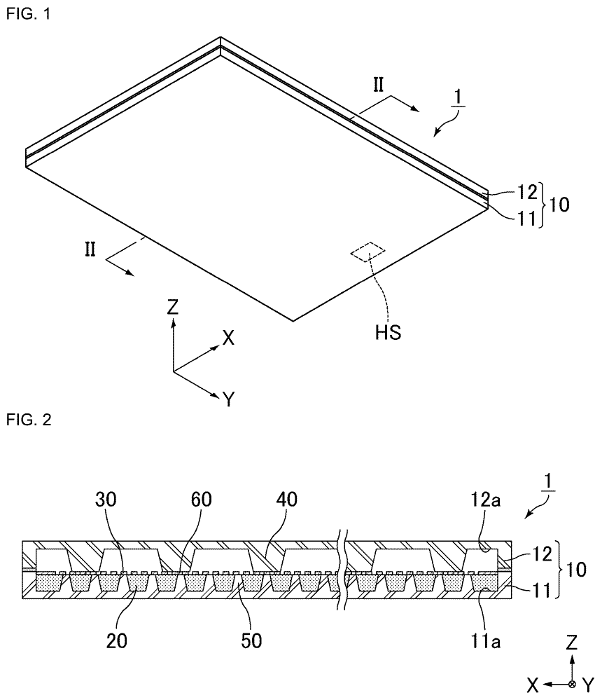

FIG. 1 is a schematic perspective view of an example of a thermal diffusion device according to a first embodiment of the present disclosure. FIG. 2 is a schematic cross-sectional view of an example of the thermal diffusion device according to the first embodiment of the present disclosure. FIG. 2 is an example of a cross-sectional view of the thermal diffusion device taken along line II-II in FIG. 1.

A vapor chamber (thermal diffusion device) 1 illustrated in FIG. 1 and FIG. 2 includes a housing 10 that is hollow and hermetically sealed. The housing 10 has a first internal surface 11a and a second internal surface 12a that face each other in a thickness direction Z. The housing 10 has an internal space. The vapor chamber 1 further includes a working medium 20 enclosed in the internal space of the housing 10, a wick 30 disposed in the internal space of the housing 10, and props 40 disposed in the internal space of the housing 10.

In the housing 10, a vaporizing portion that vaporizes the enclosed working medium 20 is formed. As illustrated in FIG. 1, a heat source HS serving as a heating element is disposed at the outer surface of the housing 10. Examples of the heat source HS include an electronic component of an electronic device, such as a central processing unit (CPU). A portion in the internal space of the housing 10 near the heat source HS and heated by the heat source HS corresponds to the vaporizing portion.

Preferably, the vapor chamber 1 is entirely planar. More specifically, preferably, the housing 10 is entirely planar. Here, the term “planar” encompasses a plate shape and a sheet shape, and indicates a shape where the dimension in a width direction X (hereafter referred to as a width) and the dimension in a length direction Y (hereafter referred to as a length) are notably greater than the dimension in a thickness direction Z (hereafter referred to as a thickness or a height), for example, a shape having a width and a length greater than or equal to ten times of the thickness, preferably, a hundred times of the thickness.

The vapor chamber 1, more specifically, the housing 10 may have any size. The width and the length of the vapor chamber 1 can be set as appropriate depending on the purpose of use. Each of the width and the length of the vapor chamber 1 is, for example, 5 mm to 500 mm, 20 mm to 300 mm, or 50 mm to 200 mm. The width and the length of the vapor chamber 1 may be the same or different.

The housing 10 preferably includes a first sheet 11 and a second sheet 12 opposing each other and having the outer edge portions joined each other.

When the housing 10 includes the first sheet 11 and the second sheet 12, the first sheet 11 and the second sheet 12 may be formed from any material that has characteristics appropriate to be used as a thermal diffusion device such as a vapor chamber, for example, thermal conductivity, strength, pliability, and flexibility. The material forming the first sheet 11 and the second sheet 12 is preferably a metal, such as copper, nickel, aluminum, magnesium, titanium, iron, or an alloy containing any of these as a main component, and particularly preferably, copper. The first sheet 11 and the second sheet 12 may be formed from the same material or different materials, but are preferably formed from the same material.

When the housing 10 includes the first sheet 11 and the second sheet 12, the first sheet 11 and the second sheet 12 are joined with each other at their outer edge portions. The first sheet 11 and the second sheet 12 may be joined with any method, for example, laser welding, resistance welding, diffusion bonding, brazing, tungsten-inert-gas (TIG) welding, ultrasonic bonding, or resin sealing, or preferably, by laser welding, resistance welding, or brazing.

Although the first sheet 11 and the second sheet 12 may have any thickness, each of the first sheet 11 and the second sheet 12 may have preferably a thickness of 10 μm to 200 μm, more preferably, 30 μm to 100 μm, or further more preferably, 40 μm to 60 μm. The first sheet 11 and the second sheet 12 may have the same thickness or different thicknesses. Each of the first sheet 11 and the second sheet 12 may have an entirely uniform thickness or may have a partially reduced thickness.

The first sheet 11 and the second sheet 12 may have any shape. For example, each of the first sheet 11 and the second sheet 12 may have the outer edge portion thicker than the other portion.

Although the entire thickness of the vapor chamber 1 may be any thickness, preferably, the entire thickness of the vapor chamber 1 is 50 μm to 500 μm.

When viewed in plan in the thickness direction Z, the housing 10 may have any shape, for example, a polygon such as a triangle or a rectangle, a circle, an ellipse, or a combination of any two or more of these. When viewed in plan, the housing 10 may have a shape of, for example, a letter L, a letter C, or a step. The housing 10 may have a through-hole. Alternatively, when viewed in plan, the housing 10 may have a shape according to the purpose of use of the thermal diffusion device such as a vapor chamber, a shape corresponding to an assembled portion of the thermal diffusion device such as a vapor chamber, or a shape corresponding to another component located near the housing 10.

The working medium 20 may be any medium that can cause a phase change between gas and liquid under the environment in the housing 10, such as water, alcohols, or alternative chlorofluorocarbon. For example, the working medium 20 is an aqueous compound, and preferably water.

The wick 30 has a capillary structure that can move the working medium 20 with capillary action. The wick 30 has, for example, a sheet shape.

The wick 30 may be formed from any material, but preferably a metal, such as copper, nickel, aluminum, magnesium, titanium, iron, or an alloy containing any of these as a main component, and particularly preferably, copper. The wick 30 and the housing 10 may be formed from the same material or different materials.

Although the wick 30 may have any size and any shape, preferably, for example, the wick 30 is continuously arranged in the internal space of the housing 10. The wick 30 may be disposed throughout in the internal space of the housing 10 when viewed in the thickness direction Z, or the wick 30 may be disposed partially in the internal space of the housing 10 when viewed in the thickness direction Z.

The wick 30 may have any thickness, for example, a thickness 5 μm to 50 μm.

In the present embodiment, the props 40 each correspond to the first support body.

The props 40 are disposed in the internal space of the housing 10 between the wick 30 and either one of the first internal surface 11a and the second internal surface 12a of the housing 10. In FIG. 2, the props 40 are disposed between the wick 30 and the second internal surface 12a of the housing 10.

The props 40 support the housing 10 and the wick 30.

The props 40 may be integrated with the housing 10, for example, formed by etching the second internal surface 12a of the housing 10.

The props 40 include, for example, multiple prismatic members. Here, the term “prismatic” indicates a shape where the ratio of the length of the long sides of the bottom surface to the length of the short sides of the bottom surface is smaller than five times.

Alternatively, the props 40 may include multiple rail members. Here, the term “rail” indicates a shape where the ratio of the length of the long sides of the bottom surface to the length of the short sides of the bottom surface is larger than or equal to five times.

When the props 40 include multiple prismatic members, the props 40 may have any shape, such as a cylinder shape, a cylindroid shape, a prism shape, a truncated cone shape, or a truncated pyramid shape.

When the props 40 include multiple rail members, the props 40 may have any cross section taken orthogonally to the extension direction, for example, a polygonal shape such as a quadrangular shape, a semicircular shape, a semielliptical shape, or a combination of any two or more of these.

As illustrated in FIG. 2, the props 40 may have a taper shape having the width further decreasing in a direction from the second internal surface 12a of the housing 10 toward the wick 30. In this structure, the flow path between the props 40 can be widened near the wick 30.

In one vapor chamber, the props 40 may have the same height or different heights.

Although the props 40 may be arranged in any manner, preferably, the props 40 are uniformly arranged in a predetermined area, or more preferably, the props 40 are uniformly arranged throughout. When the props 40 are arranged uniformly, the thermal diffusion device such as a vapor chamber can retain uniform strength throughout. For example, when the props 40 include multiple prismatic members, the props 40 are preferably arranged at a uniform center-to-center distance (pitch).

The center-to-center distance between adjacent props 40 is, for example, 100 μm to 5000 μm. A circle equivalent diameter of a cross section of each prop 40 at an end portion located closer to the wick 30 taken orthogonal to the height direction is, for example, 100 μm to 2000 μm, or preferably, 300 μm to 1000 μm. Increasing the circle equivalent diameter of the props 40 can further reduce deformation of the housing 10. On the other hand, reducing the circle equivalent diameter of the props 40 can increase the space for allowing the vapor of the working medium 20 to move. The height of the props 40 is, for example, 50 μm to 1000 μm.

The vapor chamber 1 may further include protrusions 50 disposed in the internal space of the housing 10.

In the present embodiment, the protrusions 50 each correspond to the second support body.

The protrusions 50 are disposed in the internal space of the housing 10 between the wick 30 and either one of the first internal surface 11a and the second internal surface 12a of the housing 10 opposite to the internal surface on which the first support bodies (props 40 in the present embodiment) are disposed. In FIG. 2, the protrusions 50 are disposed between the wick 30 and the first internal surface 11a of the housing 10.

The working medium 20 in a liquid phase is held between the protrusions 50. Thus, the thermal diffusion device such as a vapor chamber can improve the heat transport performance.

Herein, “the protrusions” refer to relatively high portions higher than the surroundings, and encompass, in addition to portions protruding from the internal surface of the housing, portions with a relatively larger height with the existence of hollowed portions formed in the internal surface of the housing, such as grooves.

The protrusions 50 may be integrated with the housing 10, for example, formed by etching the first internal surface 11a of the housing 10.

The protrusions 50 include, for example, multiple prismatic members. Alternatively, the protrusions 50 may include multiple rail members.

When the protrusions 50 include multiple prismatic members, the protrusions 50 may have any shape, for example, a cylinder shape, a cylindroid shape, a prism shape, a truncated cone shape, or a truncated pyramid shape.

When the protrusions 50 include multiple rail members, the protrusions 50 may have any cross section taken orthogonally to the extension direction, for example, a polygonal shape such as a quadrangular shape, a semicircular shape, a semielliptical shape, or a combination of any two or more of these.

As illustrated in FIG. 2, the protrusions 50 may have a taper shape having the width further decreasing in a direction from the first internal surface 11a of the housing 10 toward the wick 30. In this structure, the flow path between the protrusions 50 can be widened near the wick 30.

In one vapor chamber, the protrusions 50 may have the same height or different heights.

Although the protrusions 50 may be arranged in any manner, preferably, the protrusions 50 are uniformly arranged in a predetermined area, or more preferably, the protrusions 50 are uniformly arranged throughout. For example, when the protrusions 50 include multiple prismatic members, the protrusions 50 are preferably arranged at a uniform center-to-center distance (pitch).

The center-to-center distance between adjacent protrusions 50 is, for example, 60 μm to 800 μm. A circle equivalent diameter of a cross section of each protrusion 50 at an end portion located closer to the wick 30 taken orthogonal to the height direction is, for example, 20 μm to 500 μm. The height of the protrusions 50 is, for example, 10 μm to 100 μm.

The height of the protrusions 50 is preferably smaller than the height of the props 40.

The center-to-center distance between adjacent protrusions 50 is preferably smaller than the center-to-center distance between adjacent props 40.

Preferably, a circle equivalent diameter of a cross section of each protrusion 50 at an end portion located closer to the wick 30 taken orthogonal to the height direction is smaller than the circle equivalent diameter of a cross section of each prop 40 at an end portion located closer to the wick 30 taken orthogonal to the height direction.

In the vapor chamber 1, the wick 30 has through-holes 60 extending through in the thickness direction Z.

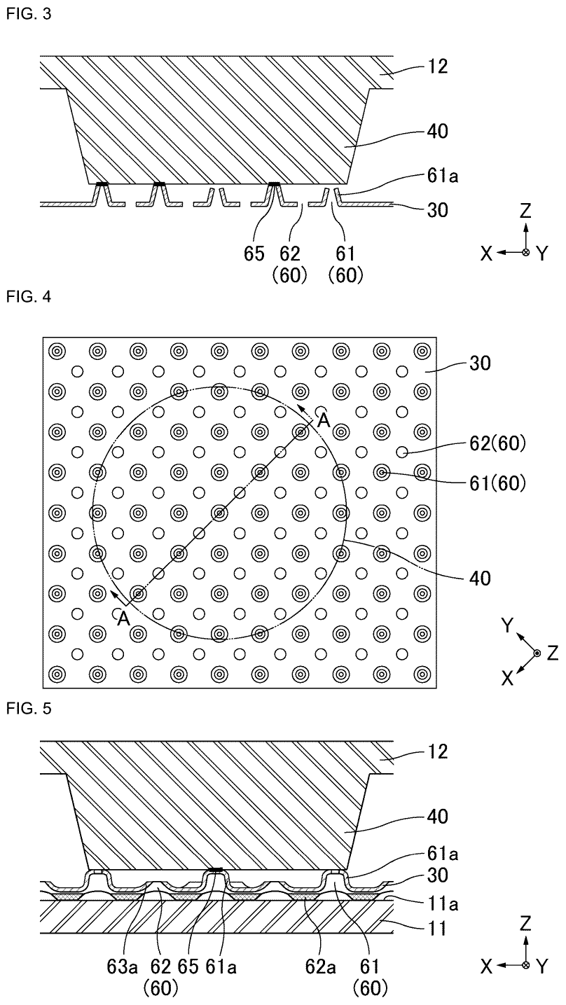

FIG. 3 is a schematic cross-sectional view of examples of a housing and a wick included in the thermal diffusion device according to the first embodiment of the present disclosure. FIG. 4 is a schematic plan view of an example of the wick illustrated in FIG. 3. FIG. 3 is a cross-sectional view of the wick taken along line A-A in FIG. 4.

In the example illustrated in FIG. 3 and FIG. 4, the wick 30 has first through-holes 61 and second through-holes 62 as the through-holes 60 extending through in the thickness direction Z.

As illustrated in FIG. 3, the wick 30 located in an area overlapping the first support body (the prop 40 in FIG. 3) in a plan view of the first internal surface 11a (refer to FIG. 2) has at least one through-hole 60, and first protrusions 61a located closer to the first support body (the prop 40 in FIG. 3) in the thickness direction Z than the peripheral edge of the through-hole 60 (for example, the second through-hole 62) located in the area.

In the example illustrated in FIG. 3, the first protrusion 61a is disposed at the peripheral edge of the corresponding first through-hole 61. The portion where the first protrusion 61a is disposed does not have to have a hole extending through the wick 30. In that case, the through-holes 60 may only include the second through-holes 62.

Preferably, the wick 30 located in an area overlapping the first support body (the prop 40 in FIG. 3) in a plan view of the first internal surface 11a has multiple first protrusions 61a. The wick 30 located in an area not overlapping the first support body (the prop 40 in FIG. 3) in a plan view of the first internal surface 11a may also include one or more first protrusions 61a.

Preferably, each of the first protrusions 61a is in contact with the prop 40 serving as the first support body. When multiple first protrusions 61a are to be provided, all the first protrusions 61a may be in contact with the prop 40, or at least one of the first protrusions 61a may be in contact with the prop 40.

When the multiple first protrusions 61a are to be in contact with the prop 40 serving as the first support body, at least one of the first protrusions 61a may be joined with the prop 40 serving as the first support body. FIG. 3 illustrates a portion where the first protrusion 61a and the prop 40 are joined as a joined portion 65. When the first protrusion 61a is joined with the prop 40, the entirety of the thermal diffusion device such as a vapor chamber has further improved strength than when the first protrusion 61a is not joined with the prop 40.

The first through-holes 61 may have any shape, but preferably have a circular or elliptic cross section taken along a plane orthogonal to the thickness direction Z.

Although the first through-holes 61 may be arranged in any manner, the first through-holes 61 are preferably arranged uniformly in a predetermined area, or more preferably arranged uniformly throughout, for example, at a uniform center-to-center distance (pitch).

The first through-holes 61 can be formed by, for example, punching metal foil forming the wick 30 with press working.

When each first protrusion 61a is to be disposed at the peripheral edge of the corresponding first through-hole 61, the first protrusion 61a may be disposed at part of the peripheral edge of the first through-hole 61, but preferably disposed at the entirety of the peripheral edge of the first through-hole 61.

The first protrusions 61a can be formed by, for example, punching metal foil forming the wick 30 with press working. When the first protrusions 61a are to be disposed at the peripheral edge of each first through-holes 61, the first protrusions 61a may be formed concurrently with the first through-holes 61, or separately from the first through-holes 61. For example, the shape of the first protrusions 61a can be adjusted by adjusting, for example, the depth of punching with press working as appropriate. The depth of punching indicates, for example, the degree to which a punch is pushed in a punching direction when punching is performed using the punch.

The first protrusions 61a may have any dimensions. For example, the height of the first protrusions 61a may be larger than the diameter of the first through-holes 61 or the second through-hole 62, smaller than the diameter of the first through-holes 61 or the second through-hole 62, or equal to the diameter of the first through-holes 61 or the second through-hole 62. All the first protrusions 61a may have the same height, or at least one or all of the first protrusions 61a may have different heights.

The second through-holes 62 may have any shape, but preferably have a circular or elliptic cross section taken along a plane orthogonal to the thickness direction Z. The second through-hole 62 may have the same shape as the first through-holes 61 or a different shape from the first through-holes 61.

Although the second through-holes 62 may be arranged in any manner, the second through-holes 62 are preferably arranged uniformly in a predetermined area, or more preferably arranged uniformly throughout, for example, at a uniform center-to-center distance (pitch).

The second through-holes 62 can be formed by, for example, punching metal foil forming the wick 30 with press working.

In the example illustrated in FIG. 3, a protrusion such as the first protrusion 61a is not disposed at the peripheral edge of the corresponding second through-hole 62. However, for example, a protrusion that protrudes toward the first support body (the prop 40 in FIG. 3) in the thickness direction Z and that is lower than the first protrusion 61a may be provided.

When the thermal diffusion device according to the first embodiment of the present disclosure includes the first support bodies and the second support bodies, the height of the second support bodies may be larger than the height of the first support bodies, but is preferably smaller than the height of the first support bodies.

When the thermal diffusion device according to the first embodiment of the present disclosure includes the first support bodies and the second support bodies, the center-to-center distance of adjacent second support bodies may be larger than the center-to-center distance of adjacent first support bodies, but is preferably smaller than the center-to-center distance of adjacent first support bodies.

When the thermal diffusion device according to the first embodiment of the present disclosure includes the first support bodies and the second support bodies, the circle equivalent diameter of a cross section of each second support body at an end portion located closer to the wick taken orthogonal to the height direction may be larger than a circle equivalent diameter of a cross section of each first support body at an end portion located closer to the wick taken orthogonal to the height direction, but preferably smaller than the circle equivalent diameter of a cross section of each first support body at an end portion located closer to the wick taken orthogonal to the height direction.

### Second Embodiment

A thermal diffusion device according to a second embodiment of the present disclosure includes, in an area that overlaps the first support body in a plan view of the first internal surface, a second protrusion that is spaced further apart from the first support body in the thickness direction than the peripheral edge of the through-hole located in the area, and the second protrusion is in contact with the internal surface of the housing.

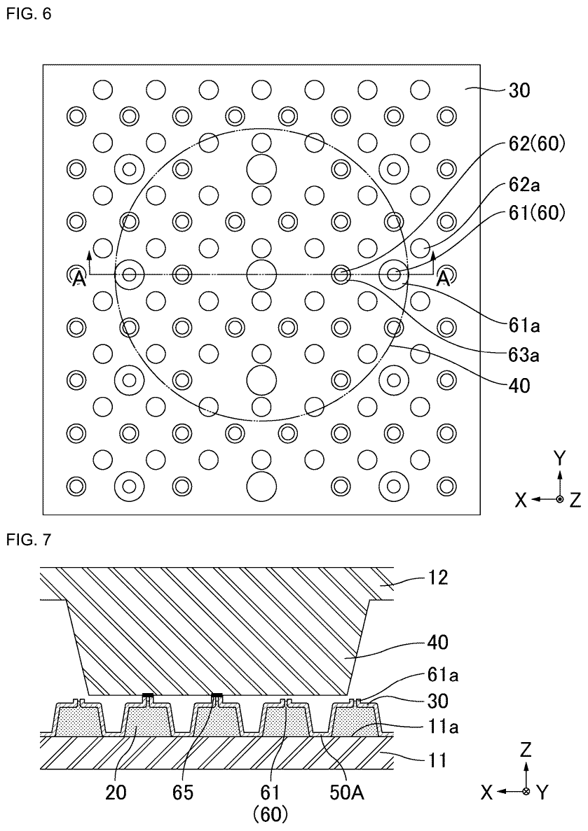

FIG. 5 is a schematic cross-sectional view of examples of a housing and a wick included in the thermal diffusion device according to the second embodiment of the present disclosure. FIG. 6 is a schematic plan view of an example of the wick illustrated in FIG. 5. FIG. 5 is a cross-sectional view of the wick illustrated taken along line A-A in FIG. 6.

In the example illustrated in FIG. 5 and FIG. 6, the wick 30 includes the first through-holes 61 and the second through-holes 62 as the through-holes 60 extending through in the thickness direction Z.

As illustrated in FIG. 5, the wick 30 located in an area overlapping the first support body (the prop 40 in FIG. 5) in a plan view of the first internal surface 11a has at least one through-hole 60, and a first protrusion 61a that is located closer to the first support body (the prop 40 in FIG. 5) in the thickness direction Z than the peripheral edge of the through-hole 60 (for example, the second through-hole 62) located in the area.

In the example illustrated in FIG. 5, the first protrusion 61a is disposed at the peripheral edge of the first through-hole 61. The portion where the first protrusion 61a is disposed does not have to have a hole extending through the wick 30. In this case, the through-holes 60 may only include the second through-holes 62.

Preferably, the wick 30 located in the area overlapping the first support body (the prop 40 in FIG. 5) in a plan view of the first internal surface 11a includes multiple first protrusions 61a. In addition, the wick 30 located in the area not overlapping the first support body (the prop 40 in FIG. 5) in a plan view of the first internal surface 11a may also include one or more first protrusions 61a.

Preferably, the first protrusions 61a are in contact with the prop 40 serving as a first support body. When multiple first protrusions 61a are to be provided, all the first protrusions 61a may be in contact with the prop 40, or at least one of the first protrusions 61a may be in contact with the corresponding prop 40.

When the multiple first protrusions 61a are to be in contact with the prop 40 serving as the first support body, at least one of the first protrusions 61a may be joined with the corresponding prop 40 serving as a first support body. FIG. 5 illustrates a portion where the first protrusion 61a and the prop 40 are joined as the joined portion 65. When the first protrusion 61a is joined with the prop 40, the entirety of the thermal diffusion device such as a vapor chamber has further improved strength than when the first protrusion 61a is not joined with the prop 40.

As illustrated in FIG. 5, the wick 30 located in the area overlapping the first support body (the prop 40 in FIG. 5) in a plan view of the first internal surface 11a has a second protrusion 62a that protrudes away from the first support body (the prop 40 in FIG. 5) in a direction opposite to the direction in which the first protrusion 61a protrudes.

Preferably, the wick 30 located in the area overlapping the first support body (the prop 40 in FIG. 5) in a plan view of the first internal surface 11a includes multiple second protrusions 62a. In addition, the wick 30 located in an area not overlapping the first support body (the prop 40 in FIG. 5) in a plan view of the first internal surface 11a may also include one or more second protrusions 62a.

The second protrusion 62a is in contact with either one of the first internal surface 11a and the second internal surface 12a of the housing 10 away from the first support body (the prop 40 in FIG. 5). In FIG. 5, the second protrusion 62a is in contact with the first internal surface 11a of the housing 10.

The working medium 20 in a liquid phase can be held between the second protrusions 62a. In this case, the thermal diffusion device such as a vapor chamber can have improved heat transport performance.

When the multiple second protrusions 62a are to be in contact with the first internal surface 11a of the housing 10, all the second protrusions 62a may be in contact with the first internal surface 11a of the housing 10, or at least one of the second protrusions 62a may be in contact with the first internal surface 11a of the housing 10.

When the multiple second protrusions 62a are to be in contact with the first internal surface 11a of the housing 10, at least one of the second protrusions 62a may be joined with the first internal surface 11a of the housing 10. When the second protrusion 62a is joined with the first internal surface 11a of the housing 10, the entirety of the thermal diffusion device such as a vapor chamber has further improved strength than when the second protrusion 62a is not joined with the first internal surface 11a.

The second protrusions 62a can be formed by, for example, punching metal foil forming the wick 30 with press working. For example, the shape of the second protrusions 62a can be adjusted by adjusting, for example, the depth of punching with press working as appropriate.

The second protrusions 62a may have any dimensions. For example, the height of the second protrusions 62a may be larger than the diameter of the first through-holes 61 or the second through-hole 62, smaller than the diameter of the first through-holes 61 or the second through-hole 62, or equal to the diameter of the first through-holes 61 or the second through-hole 62. The height of the second protrusions 62a may be larger than the height of the first protrusions 61a, smaller than the height of the first protrusions 61a, or equal to the height of the first protrusions 61a. All the second protrusions 62a may have the same height, or at least one or all of the first protrusions 61a may have different heights.

As illustrated in FIG. 5, third protrusions 63a shorter than the first protrusions 61a and protruding toward the first support body (the prop 40 in FIG. 5) in the thickness direction Z may be disposed at the peripheral edge of the second through-hole 62. The height of the third protrusions 63a may be larger than the height of the second protrusions 62a, smaller than the height of the second protrusions 62a, or the same as the height of the second protrusions 62a. All the third protrusions 63a may have the same height, or at least one or all of the third protrusions 63a may have different heights. No third protrusion 63a may be disposed at the peripheral edge of at least one of the second through-holes 62.

When the third protrusion 63a are to be disposed at the peripheral edge of the corresponding second through-hole 62, the third protrusion 63a may be disposed at part of the peripheral edge of the corresponding second through-hole 62, but preferably, disposed at the entirety of the peripheral edge of the second through-hole 62.

### Third Embodiment

In a thermal diffusion device according to a third embodiment of the present disclosure, second support bodies are disposed in the internal space of the housing, and the second support bodies are integrated with the wick.

Herein, that “the second support bodies are integrated with the wick” indicates that there is no interface between the second support bodies and the wick, more specifically, no boundary is identifiable between the second support bodies and the wick. For example, in a structure where copper pillars serving as the second support bodies and a copper mesh serving as the wick are fixed by, for example, diffusion bonding or spot welding, joining the second support bodies and the wick over the entire surface is difficult, and thus, a gap is partially left between the second support bodies and the wick. In this structure, a boundary between the second support bodies and the wick is identifiable, and thus, in such a structure, the second support bodies and the wick are regarded as not being integrated with each other.

In the example described below, the first support bodies are embodied by props, and the second support bodies are embodied by protrusions, but the first support bodies may be embodied by protrusions and the second support bodies may be embodied by props.

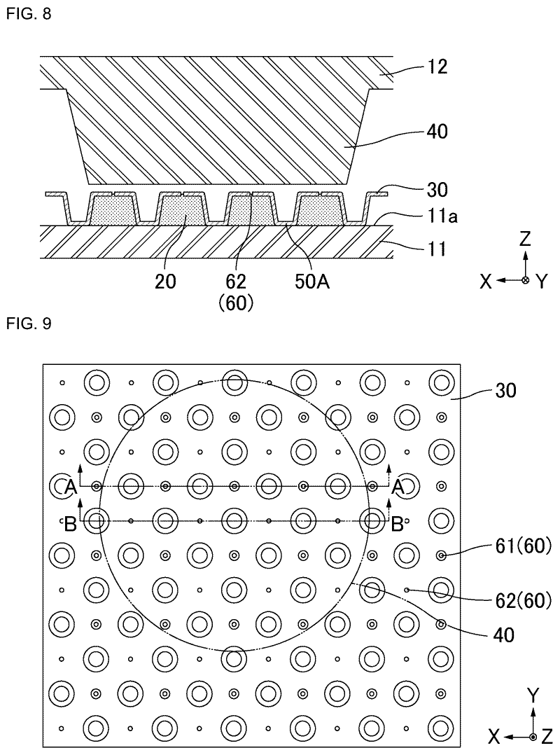

FIG. 7 is a schematic cross-sectional view of examples of a housing and a wick of the thermal diffusion device according to the third embodiment of the present disclosure. FIG. 8 is a schematic cross-sectional view of examples of the housing and the wick at different positions from FIG. 7. FIG. 9 is a schematic plan view of an example of the wick illustrated in FIG. 7 and FIG. 8. FIG. 7 is a cross- sectional view of the wick taken along line A-A in FIG. 9, and FIG. 8 is a cross-sectional view of the wick taken along line B-B in FIG. 9.

In the example illustrated in FIG. 7, FIG. 8, and FIG. 9, the wick 30 has the first through-holes 61 and the second through-holes 62 as the through-holes 60 extending through in the thickness direction Z.

As illustrated in FIG. 7, the wick 30 located in the area overlapping the first support body (the prop 40 in FIG. 7) in a plan view of the first internal surface 11a has at least one through-hole 60, and a first protrusion 61a located closer to the first support body (the prop 40 in FIG. 7) in the thickness direction Z than the peripheral edge of the through-hole 60 (for example, the second through-hole 62) located in the area.

In the example illustrated in FIG. 7, the first protrusion 61a is disposed at the peripheral edge of the corresponding first through-hole 61. The portion where the first protrusion 61a is disposed does not have to have a hole extending through the wick 30. In this case, the through-holes 60 may only include the second through-holes 62.

Preferably, the wick 30 located in the area overlapping the first support body (the prop 40 in FIG. 7) in a plan view of the first internal surface 11a includes multiple first protrusions 61a. In addition, the wick 30 located in the area not overlapping the first support body (the prop 40 in FIG. 7) in a plan view of the first internal surface 11a may include one or more first protrusions 61a.

Preferably, the first protrusions 61a are in contact with the prop 40 serving as a first support body. When multiple first protrusions 61a are to be provided, all the first protrusions 61a may be in contact with the corresponding prop 40, or at least one of the first protrusions 61a may be in contact with the corresponding prop 40.

When the multiple first protrusions 61a are to be in contact with the prop 40 serving as the first support body, at least one of the first protrusions 61a may be joined with the prop 40 serving as the first support body. FIG. 7 illustrates a portion where the first protrusion 61a and the prop 40 are joined as the joined portion 65. When the first protrusion 61a is joined with the prop 40, the entirety of the thermal diffusion device such as a vapor chamber has further improved strength than when the first protrusion 61a is not joined with the prop 40.

In the example illustrated in FIG. 8, no protrusion such as the first protrusions 61a is disposed at the peripheral edge of the second through-hole 62, but, for example, a protrusion that protrudes toward the first support body (the prop 40 in FIG. 8) in the thickness direction Z and that is lower than the first protrusions 61a may be provided.

In the example illustrated in FIG. 7 and FIG. 8, protrusions 50A serving as the second support bodies are integrated with the wick 30.

The protrusions 50A may be formed in any method. For example, part of metal foil forming the wick 30 is bent down by processing such as press working into hollows, to form the protrusions 50A. The hollows in the protrusions 50A define vapor spaces, and thus the thermal conductivity improves. The press working to form the protrusions 50A and the press working to form the through-holes 60 such as the first through-holes 61 or the second through-holes 62 may be collectively performed.

Preferably, the metal foil has a uniform thickness before being processed with, for example, press working. However, metal foil may be thinned at a bent portion. Thus, as in the example illustrated in FIG. 7 and FIG. 8, preferably, the thickness of the protrusions 50A is the same as the thickness of the wick 30 or smaller than the thickness of the wick 30.

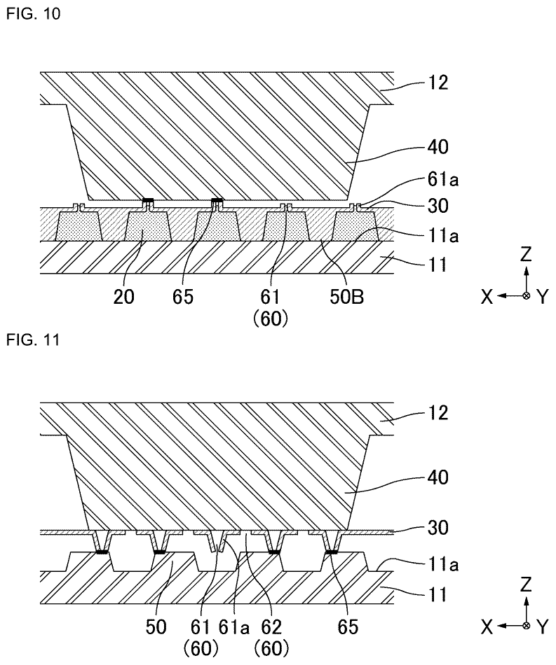

FIG. 10 is a schematic cross-sectional view of other examples of a housing and a wick included in the thermal diffusion device according to the third embodiment of the present disclosure.

In the example illustrated in FIG. 10, protrusions 50B are not hollowed.

The wick 30 and the protrusions 50B may be formed from any material, for example, a resin, a metal, ceramics, or a mixture or a laminate of any two or more of these. Preferably, the material forming the wick 30 and the protrusions 50B is a metal.

The wick 30 and the protrusions 50B can be formed by a method such as etching, printing involving multilayer application, or another multilayer technique.

The protrusions 50A or 50B include, for example, multiple prismatic members. Alternatively, the protrusions 50A or 50B may include multiple rail members.

As illustrated in FIG. 7 or FIG. 10, the protrusions 50A or 50B may have a taper shape having the width further decreasing in a direction from the wick 30 toward the first internal surface 11a of the housing 10. In this structure, the flow path between the protrusions 50A or 50B can be widened near the housing 10.

In the thermal diffusion device according to the third embodiment of the present disclosure, the height of the second support bodies may be larger than the height of the first support bodies, but is preferably smaller than the height of the first support bodies.

In the thermal diffusion device according to the third embodiment of the present disclosure, the center-to-center distance between adjacent second support bodies may be larger than the center-to-center distance between adjacent first support bodies, but is preferably smaller than the center-to-center distance between adjacent first support bodies.

In the thermal diffusion device according to the third embodiment of the present disclosure, a circle equivalent diameter of a cross section of each second support body at an end portion located closer to the wick taken orthogonal to the height direction may be larger than a circle equivalent diameter of a cross section of each first support body at an end portion located closer to the wick taken orthogonal to the height direction, but is preferably smaller than a circle equivalent diameter of a cross section of each first support body at an end portion located closer to the wick taken orthogonal to the height direction.

### Fourth Embodiment

In a thermal diffusion device according to a fourth embodiment of the present disclosure, the second support bodies are disposed in the internal space of the housing, and the height of the second support bodies is larger than the height of the first support bodies.

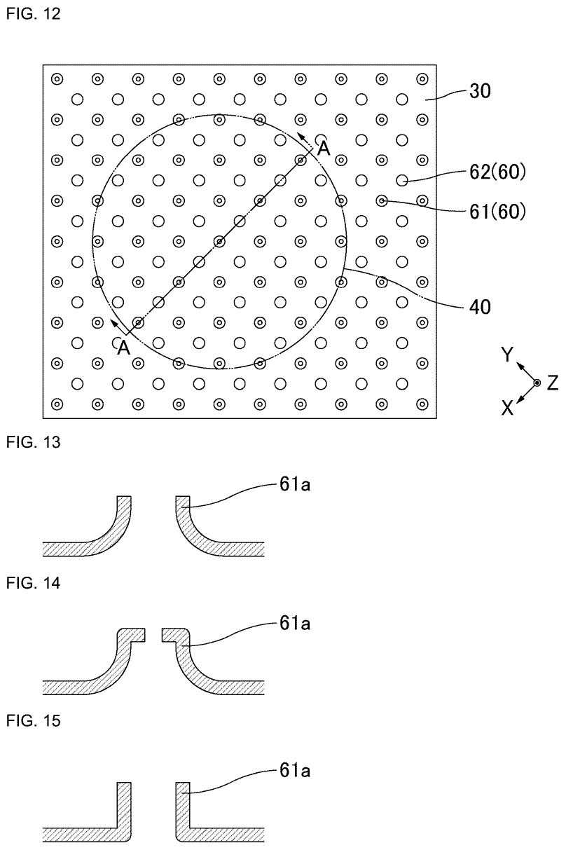

FIG. 11 is a schematic cross-sectional view of examples of a housing and a wick included in a thermal diffusion device according to a fourth embodiment of the present disclosure. FIG. 12 is a schematic plan view of an example of the wick illustrated in FIG. 11. FIG. 11 is a cross-sectional view of the wick taken along line A-A in FIG. 12.

In the present embodiment, the protrusions 50 correspond to first support bodies, and the props 40 correspond to second support bodies.

In the example illustrated in FIG. 11 and FIG. 12, the wick 30 has the first through-holes 61 and the second through-holes 62 as the through-holes 60 extending through in the thickness direction Z.

As illustrated in FIG. 11, the wick 30 located in an area overlapping the second support body (the protrusion 40 in FIG. 11) in a plan view of the first internal surface 11a includes at least one through-hole 60, and a first protrusion 61a that is located closer to the first support body (the protrusion 50 in FIG. 11) in the thickness direction Z than the peripheral edge of the through-hole 60 (for example, the second through-hole 62) located in the area.

In the example illustrated in FIG. 11, the first protrusion 61a is located at the peripheral edge of the corresponding first through-hole 61. The portion where the first protrusion 61a is disposed does not have to have a hole extending through the wick 30. In this case, the through-holes 60 may only include the second through-holes 62.

Preferably, the wick 30 located in the area overlapping the second support body (the protrusion 40 in FIG. 11) in a plan view of the first internal surface 11a includes multiple first protrusions 61a. In addition, the wick 30 located in the area not overlapping the second support body (the protrusion 40 in FIG. 11) in a plan view of the first internal surface 11a may also include one or more first protrusions 61a.

Preferably, the first protrusions 61a are in contact with the protrusions 50 serving as the first support bodies. When multiple first protrusions 61a are to be provided, all the first protrusions 61a may be in contact with the protrusions 50, or at least one of the first protrusions 61a may be in contact with the corresponding protrusion 50.

When the multiple first protrusions 61a are to be in contact with the protrusions 50 serving as first support bodies, at least one of the first protrusions 61a may be joined with the corresponding protrusion 50 serving as a first support body. FIG. 11 illustrates a portion where the first protrusion 61a and the protrusion 50 are joined as the joined portion 65. When the first protrusion 61a is joined with the protrusion 50, the entirety of the thermal diffusion device such as a vapor chamber has further improved strength than when the first protrusion 61a is not joined with the protrusion 50.

In the example illustrated in FIG. 11, no protrusion such as the first protrusion 61a is disposed at the peripheral edge of the second through-hole 62, but, for example, a protrusion that protrudes toward the first support body (the protrusion 50 in FIG. 11) in the thickness direction Z and that is lower than the first protrusions 61a may be provided.

### Other Embodiments

The thermal diffusion device according to the present disclosure is not limited to those according to the above embodiments, but may be applied or modified in various manners in regard to, for example, the structure or the manufacturing conditions of a thermal diffusion device, within the scope of the present disclosure.

In the thermal diffusion device according to the present disclosure, the first protrusion disposed on the wick may have any shape.

FIG. 13 is a schematic cross-sectional view of a first modification example of the shape of the first protrusion.

As illustrated in FIG. 13, in a cross section taken in the thickness direction, the distance between portions on the outer wall of the first protrusion 61a may decrease further in a direction in which the first protrusion 61a protrudes toward the first support body (upward in FIG. 13). In this case, in a cross section taken in the thickness direction, the first protrusion 61a may have a shape protruding toward the first support body (upward in FIG. 13), or protruding away from the first support body (downward in FIG. 13).

Alternatively, in a cross section taken in the thickness direction, the distance between portions on the outer wall of the first protrusion 61a may increase in a direction in which the first protrusion 61a protrudes toward the first support body. In this case, in a cross section taken in the thickness direction, the first protrusion 61a may have a shape protruding toward the first support body, or protruding away from the first support body.

FIG. 14 is a schematic cross-sectional view of a second modification example of the shape of the first protrusion.

As illustrated in FIG. 14, the first protrusions 61a may each have, at the end portion closer to the first support body (upper side in FIG. 14), a lid portion to narrow the opening of the first protrusion 61a.

FIG. 15 is a schematic cross-sectional view of a third modification example of the shape of the first protrusion.

As illustrated in FIG. 15, in a cross section taken in the thickness direction, the distance between portions on the outer wall of the first protrusion 61a may be uniform in a direction in which the first protrusion 61a protrudes toward the first support body (upward in FIG. 15). In this case, the first protrusions 61a may each have, at the end portion closer to the first support body (upper side in FIG. 15), a lid portion to narrow the opening of the first protrusion 61a.

In the thermal diffusion device according to the present disclosure, when the wick has a second protrusion, the second protrusion may have any shape.

In the thermal diffusion device according to the present disclosure, the wick may have a through-hole other than the first through-hole and the second through-hole.

In the thermal diffusion device according to the present disclosure, the wick may be disposed in any manner. For example, the wick may be disposed throughout in the internal space of the housing, or in part of the internal space of the housing.

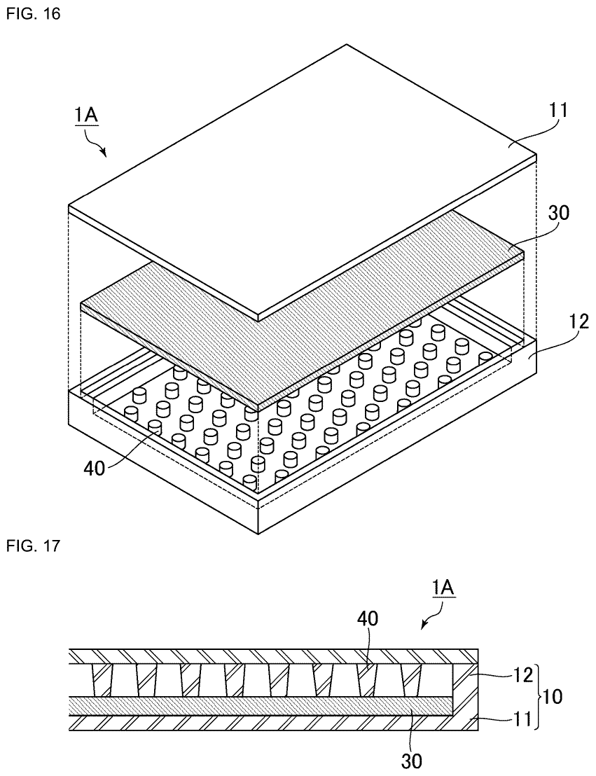

FIG. 16 is a schematic perspective view of a thermal diffusion device according to a first modification example of the present disclosure. FIG. 17 is a schematic cross-sectional view of the thermal diffusion device according to the first modification example of the present disclosure.

In a vapor chamber (thermal diffusion device) 1A illustrated in FIG. 16 and FIG. 17, the wick 30 is disposed throughout in the internal space of the housing 10.

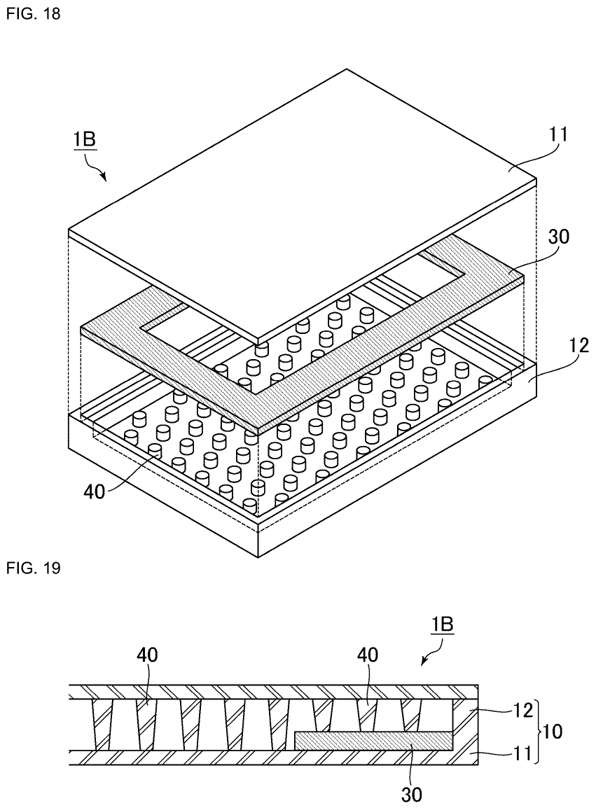

FIG. 18 is a schematic perspective view of a thermal diffusion device according to a second modification example of the present disclosure. FIG. 19 is a schematic cross- sectional view of the thermal diffusion device according to the second modification example of the present disclosure.

In a vapor chamber (thermal diffusion device) 1B illustrated in FIG. 18 and FIG. 19, the wick 30 is disposed along the outer periphery of the internal space of the housing 10. The vapor chamber 1B has a wider space for allowing the vapor of a working medium (not illustrated) to move than the vapor chamber 1A.

In the thermal diffusion device according to the present disclosure, the housing may include one or more vaporizing portions. More specifically, one or more heat sources may be disposed on the outer wall surface of the housing.

In the thermal diffusion device according to the present disclosure, when the housing includes a first sheet and a second sheet, the first sheet and the second sheet may overlap each other while having their end portions aligned or misaligned with each other.

In the thermal diffusion device according to the present disclosure, when the housing includes a first sheet and a second sheet, the material forming the first sheet and the material forming the second sheet may differ from each other. For example, when the first sheet is formed from a material with high strength, the stress exerted on the housing can be dispersed. When both sheets are formed from different materials, one of the sheets may have a first function, and the other sheet may have a second function. Examples of the above functions include, but not limited a thermal conduction function and an electromagnetic shielding function.

The thermal diffusion device according to the present disclosure may be installed on an electronic device for the purpose of heat dissipation. Thus, an electronic device including the thermal diffusion device according to the present disclosure is also included in the present disclosure. Examples of the electronic device according to the present disclosure include smartphones, tablet terminals, laptop computers, game machines, and wearable devices. As described above, the thermal diffusion device according to the present disclosure can independently operate without using an external power, and quickly diffuse heat two-dimensionally using evaporative latent heat and condensed latent heat of the working medium. Thus, the electronic device including the thermal diffusion device according to the present disclosure can effectively perform heat dissipation in a limited space inside the electronic device.

The following details are disclosed herein.
<1> A thermal diffusion device, comprising: a housing having a first internal surface and a second internal surface opposing each other in a thickness direction so as to define an internal space; a working medium in the internal space of the housing; a wick in the internal space of the housing; and a first support body in the internal space of the housing between the wick and either one of the first internal surface and the second internal surface of the housing, wherein the wick has one or more through-holes extending therethrough in the thickness direction, and wherein the wick, in an area overlapping the first support body in a plan view of the first internal surface, includes: at least one of the one or more through-holes, and a first protrusion that is closer to the first support body in the thickness direction than a peripheral edge of the at least one of the one or more through-holes in the area.
<2> The thermal diffusion device according to <1>, wherein the one or more through-holes include a first through-hole having a peripheral edge with the first protrusion is disposed.
<3> The thermal diffusion device according to <1> or <2>, wherein the first protrusion is in contact with the first support body.
<4> The thermal diffusion device according to any one of <1>to <3>, wherein the wick, in the area overlapping the first support body in the plan view of the first internal surface, includes a second protrusion that protrudes away from the first support body.
<5> The thermal diffusion device according to <4>, wherein the second protrusion is in contact with either one of the first internal surface and the second internal surface of the housing.
<6> The thermal diffusion device according to any one of <1> to <3>, further comprising: a second support body in the internal space of the housing, and between the wick and either one of the first internal surface and the second internal surface of the housing on a side of the wick opposite to the first support body.
<7> The thermal diffusion device according to <6>, wherein the second support body has a smaller height than that of the first support body.
<8> The thermal diffusion device according to <6> or <7>, wherein the second support body is integrated with the wick.
<9> The thermal diffusion device according to <6> or <8>, wherein the second support body has a larger height than the first support body.
<10> The thermal diffusion device according to any one of <6> to <9>, wherein the wick, in the area overlapping the first support body in the plan view of the first internal surface, includes a second protrusion that protrudes away from the first support body, and wherein the second protrusion is in contact with the second support body.
<11> The thermal diffusion device according to any one of <1> to <10>, wherein, in a cross section in the thickness direction, a distance between portions on an outer wall of the first protrusion decreases in a direction in which the first protrusion protrudes toward the first support body.
<12> The thermal diffusion device according to any one of <1> to <10>, wherein, in a cross section in the thickness direction, a distance between portions on an outer wall of the first protrusion is uniform in a direction in which the first protrusion protrudes toward the first support body.
<13> The thermal diffusion device according to any one of <1> to <12>, wherein the first protrusion includes, at an end portion thereof closer to the first support body, a lid portion that narrows an opening of the first protrusion.
<14> An electronic device, comprising the thermal diffusion device according to any one of <1> to <13>.

A thermal diffusion device according to the present disclosure is usable in a wide range of the purpose of use in the field of, for example, personal digital assistants. For example, the thermal diffusion device according to the present disclosure is usable to lower the temperature of a heat source such as a central processing unit (CPU) and to elongate the operating time of an electronic device, and is applicable to, for example, smartphones, tablet terminals, and laptop computers.

### REFERENCE SIGNS LIST

1, 1A, 1B vapor chamber (thermal diffusion device)
10 housing
11 first sheet
11a first internal surface
12 second sheet
12a second internal surface
20 working medium
30 wick
40 prop
50, 50A, 50B protrusion
60 through-hole
61 first through-hole
61a first protrusion
62 second through-hole
62a second protrusion

63a third protrusion
joined portion
HS heat source
X width direction
Y length direction
Z thickness direction

1. A thermal diffusion device, comprising:
a housing having a first internal surface and a second internal surface opposing each other in a thickness direction so as to define an internal space;
a working medium in the internal space of the housing;
a wick in the internal space of the housing; and
a first support body in the internal space of the housing between the wick and either one of the first internal surface and the second internal surface of the housing,
wherein the wick has one or more through-holes extending therethrough in the thickness direction, and
wherein the wick, in an area overlapping the first support body in a plan view of the first internal surface, includes:
at least one of the one or more through-holes, and
a first protrusion that is closer to the first support body in the thickness direction than a peripheral edge of the at least one of the one or more through-holes in the area.

2. The thermal diffusion device according to claim 1, wherein the one or more through-holes include a first through-hole having a peripheral edge with the first protrusion.

3. The thermal diffusion device according to claim 1, wherein the first protrusion is in contact with the first support body.

4. The thermal diffusion device according to claim 1, wherein the wick, in the area overlapping the first support body in the plan view of the first internal surface, includes a second protrusion that protrudes away from the first support body.

5. The thermal diffusion device according to claim 4, wherein the second protrusion is in contact with either one of the first internal surface and the second internal surface of the housing.

6. The thermal diffusion device according to claim 1, further comprising:
a second support body in the internal space of the housing, and between the wick and either one of the first internal surface and the second internal surface of the housing on a side of the wick opposite to the first support body.

7. The thermal diffusion device according to claim 6, wherein the second support body has a smaller height than that of the first support body.

8. The thermal diffusion device according to claim 6, wherein the second support body is integrated with the wick.

9. The thermal diffusion device according to claim 6, wherein the second support body has a larger height than the first support body.

10. The thermal diffusion device according to claim 6,
wherein the wick, in the area overlapping the first support body in the plan view of the first internal surface, includes a second protrusion that protrudes away from the first support body, and
wherein the second protrusion is in contact with the second support body.

11. The thermal diffusion device according to claim 1, wherein, in a cross section in the thickness direction, a distance between portions on an outer wall of the first protrusion decreases in a direction in which the first protrusion protrudes toward the first support body.

12. The thermal diffusion device according to claim 1, wherein, in a cross section in the thickness direction, a distance between portions on an outer wall of the first protrusion is uniform in a direction in which the first protrusion protrudes toward the first support body.

13. The thermal diffusion device according to claim 1, wherein the first protrusion includes, at an end portion thereof closer to the first support body, a lid portion that narrows an opening of the first protrusion.

14. The thermal diffusion device according to claim 4, wherein the wick, in the area overlapping the first support body in the plan view of the first internal surface, includes a third protrusion that protrudes towards the first support body.

15. The thermal diffusion device according to claim 14, wherein the first protrusion is in contact with the first support body, and the second protrusion is in contact with either one of the first internal surface and the second internal surface of the housing.

16. The thermal diffusion device according to claim 14, wherein a height of the third protrusions is shorter than that of the first protrusions.

17. The thermal diffusion device according to claim 14, wherein the one or more through-holes include:
a first through-hole having a peripheral edge with the first protrusion; and
a second through-hole having a peripheral edge with the third protrusion.

18. An electronic device comprising the thermal diffusion device according to claim 1.
